(19) United States
(12) Patent Application Publication
(10) Pub. No.: US 2009/0309094 A1
(43) Pub. Date: Dec. 17, 2009

(54) COLOR CONTROLLED ELECTROLUMINESCENT DEVICES

(75) Inventors: Gitti Frey, Haifa (IL); Eyal Aharon, Haifa (IL); Michael Kalina, Haifa (IL)

Correspondence Address: WINSTON & STRAWN LLP;PATENT DEPARTMENT, 1700 K STREET, N.W., WASHINGTON, DC, 20006, US

(73) Assignee: Technion Research and Development Foundation Ltd., Haifa (IL)

(21) Appl. No.: 12/280,763

(22) PCT Filed: Feb. 27, 2007
(86) PCT No.: PCT/IL07/00255

§ 371 Date: Nov. 12, 2008

Related U.S. Application Data
(60) Provisional application No. 60/776,663, filed on Feb. 27, 2006.

(51) Int. Cl. H01L 51/54; B32B 9/00; B32B 27/30; B32B 27/00; H01J 1/63; B32B 37/00; B32B 38/16

(52) U.S. Cl. 257/40; 428/690; 428/691; 428/500; 428/421; 313/504; 156/60; 156/281; 156/64; 257/E51.026; 977/755

(57) ABSTRACT

An organic electroluminescent device of a composite material that includes at least two emissive polymers confined into a layered inorganic host matrix, which effectively isolates the polymer chains from their neighbors, and a method for manufacturing same. The isolation of the emitting chains inhibits energy transfer and exciton diffusion between polymer chains, such that the electrically generated excitons recombine radiatively before their energy could be funneled to the emissive moiety with the lowest band gap. The emission color of such a composite is a combination of the emission of the confined polymers, and can be either white light, or can be tuned by selection of the ratio of the mixtures to output light of any desired color. The different polymers can either be mixed and then intercalated into the host matrix, or they can each be intercalated separately into the host matrix and the resulting composites mixed.

### FIELD OF THE INVENTION

The present invention relates to materials and methods for electroluminescent device construction and the control of the color output thereof, especially for use in white light emission devices, and for devices in which the emission color is selected by simple composition changes of the electroluminescent material.

### BACKGROUND OF THE INVENTION

The commercial interest in cheap, large area, efficient white-emitting devices for display back-lighting and alternative solid-state lighting has focused attention towards solution-processed polymer light-emitting diodes (PLEDs). Two mechanisms have been proposed for the generation of white light in a polymer device. In the first approach, charges recombine radiatively in discrete polymer layers each emitting in a different color. Simultaneous emission from several layers at once provides the desired white emission. Such multilayered device methods have been described by Kido et al. [J. Kido, M. Kimura, K. Nagai, Science, 267, p 1332 (1995)], by Xie et al. [Z. Y Xie, Y Liu, J. S. Huang, Y Wang, C. N. Li, S. Y Liu, J. C. Chen, Synth. Met. 106, p 71 (1999)], by Ogura et al. [T. Ogura, T. Yamashita, M. Yoshida, K. Emoto, S, Nakajima, U.S. Pat. No. 5,283,132], and by Deshpande et al. [R. S. Deshpande, V. Bulovic, S. R. Forrest, Appl. Phys. Lett. 75, p. 888, (1999)]. Solution processing a polymer multilayer stack is, however, challenging because most high photoluminescent polymers are soluble in similar solvents and sequential deposition will result in layer intermixing. Controlling polymer phase-separation to form multi-layers with predetermined layer thicknesses may therefore be a complex process, and the production of useful devices generally has involved use of trial and error methods to obtain the desired thickness of each layer. Furthermore, such multilayer devices may also suffer from a change of the emitted color with the applied bias, due to shifting of the emission zone through the stack.

Due to these limitations, another method of generating white light EL emission is by using a single layer EL material, in which small amounts of red and green-emissive EL moieties are introduced into a blue-emitting EL polymer host by grafting or doping. Energy transfer from the wide-gap host polymer to the smaller-gap species, followed by concurrent emission from the three chromophores, yields white light. The energy transfer from the host to the dopant generally occurs via Forster-type transfer, i.e. dipole-dipole interactions; and mainly Dexter-type transfer, i.e. exciton (electron-hole pair) diffusion. Some examples of such devices and methods have been described by Granstrom et al. [M. Granstrom, O. Ingans, Appl. Phys. Lett. 68, p 147. (1996)], Kido et al. [J. Kido, H. Shionoya, K. Nagai, Appl. Phys. Lett. 67, 2281 (1995)], Shi et al. [J. Shi, C. W. Tang, U.S. Pat. No. 5,683,823], and Chen et al. [S.-A. Chen, E.-C. Chang, K.-R. Chuang, U.S. Pat. No. 6,127,693]

Although the process in this method may be considered to be simpler than the first method, the “purity” and stability of such white emission, however, is generally sensitive to synthesis and processing parameters and device operating conditions. Particularly, when blending or doping components having good miscibility between them, due to energy transfer from the high-bandgap components to the low-bandgap components, the spectrum of the host material may vary greatly with blending or doping level. Thus, it is difficult to predict the final emission spectrum. Additionally, when three or more components are blended to prepare a white-light-emitting material, it may be more difficult to control energy transfer between the components. Successful white-light-emission depends on how energy transfer between the components to be blended is efficiently controlled. Consequently, achieving pure and stable white electroluminescence in such PLEDs has often required trial-and-error efforts with respect to most, if not all, stages of light emitting materials design, film processing, and device fabrication. US Patent application 2004/0033388; to Kim, Young-Chul, et al.: entitled “Organic white-light-emitting blend materials and electroluminescent devices fabricated using the same” describes such a method and device in which the Forster energy transfer is efficiently controlled by performing light doping. In this application, the energy transfer occurs only between a host which is a donor and each dopant which is an acceptor, while the energy transfer between dopants is efficiently blocked.

A further PLED method has been described in U.S. Pat. No. 6,593,688 to Park, O-Ok, et al., entitled “Electroluminescent devices employing organic luminescent material/clay nanocomposites”. This patent describes a organic luminescent material/clay nanocomposite incorporating a single emissive organic species, which is prepared by blending the organic luminescent material with a nanoclay. The nanoclay is described therein as including materials having an insulating property, and the 2-dimensional plate structure of the nanoclay is operative to block electron or hole transport so that electric charges are collected between the plates, resulting in the asserted improvement of the electron-hole recombination probability or the EL efficiency. Furthermore, the organic EL material/nanoclay composite is described as also considerably decreasing the penetration of oxygen and moisture, which, in turn, improves the stability of the device. However, since the nanoclay is an insulator, it would appear that it does not play an active part in the charge transport mechanisms operative in a device.

There therefore exists a need for a PLED whose spectral emissive properties can be better controlled, such that the device can be readily tailored to provide either a white light emission, or any other predetermined color, without undue trial and error procedures.

The disclosures of each of the publications mentioned in this section and in other sections of the specification, are hereby incorporated by reference, each in its entirety.

### SUMMARY OF THE INVENTION

The present invention seeks to provide a new organic electroluminescence scheme utilizing a single nanocomposite material, comprising a number of different luminescent polymer components incorporated into a layered matrix, such that chain-chain interactions are hindered, and energy transfer among the components by Forster energy transfer and by exciton diffusion is inhibited. The matrix is preferably constructed of a semiconducting material, such that the charge transport properties of the matrix are not hindered. The prevention of energy transfer between the different incorporated components means that exciton recombination occurs radiatively at each of the locations where the excitons are formed, each location being associated with its own component, thereby enabling essentially simultaneous emission of the color associated with each local component, and without significantly influencing the emission of neighboring components. Once such a situation is achieved, it becomes possible to synthesize any color emission required, whether white or of a specific color, by a simple selection procedure of the component mixture concentrations. Such a scheme enables the preparation of organic electroluminescent (hereinafter EL) white-light-emitting materials with improved color stability and light-emitting efficiency. Additionally, such a scheme enables the “tuning” of the material to a specific desired emitted wavelength region by means of a readily predetermined mixture of the EL-active material components.

Preferably, the host matrix is a semiconductor or a blend of semiconductor and insulators. Use of an insulating matrix, as described in the Park et al prior art, may provide transparency for the emitted light, but it may impede the efficient transport of the charge carriers. The semi-conducting matrix of the present invention, on the other hand, though it may absorb some of the emitted light, is capable of transporting the carriers, thus enabling significantly more efficient and simpler operation of devices constructed using these materials. A balanced blend of two host matrices may preferably be used. According to preferred embodiments of the present invention, tin sulphide SnS₂ may be used as a semiconductor matrix material, with or without the addition of MoO₃ as an insulator matrix material. The use of solely insulator host matrices may be envisioned, but would likely entail the application of higher fields in order to render such devices operational, and hence may be less reliable and less efficient. This is apparent from the article by J. H. Park et al, entitled “Stabilized Blue Emission from Polymer-Dielectric Nanolayer Nanocomposites” published in Adv. Funct. Mater., Vol. 14, No. 4, pp. 377-382 (April 2004), and in the article by M. Eckel and G. Decher, entitled “Tuning the Performance of Layer-by-Layer Assembled Organic Light Emitting Diodes by Controlling the Position of Isolating Clay Barrier Sheets” published in Nonoletters, Vol 1(1), pp. 45-49 (2001), from where it can be seen that the reported the turn-on fields of such devices with insulating layered hosts, are considerably higher than those of similar devices made using semiconductor layered hosts, such as are reported in the article by some of the inventors of the present application, entitled “Stable Blue Emission from a Polyfluorine/layered Compound Guest/host Nanocomposite”, presented at the 6^{th}. International Symposium on Functional pi-Electron Systems, Cornell University, Ithaca, June 2004, and published in Adv. Funct. Mater., Vol. 16, No. 7, pp. 980-986 (April 2006).

Two different types of nanocomposites are proposed, according to different preferred embodiments of the present invention. In the first type, a polymer blend of the EL components is preferably first prepared, and this blend is then intercalated into the inorganic layered matrix. This type is known herein as a ‘composite of blends’.

In the second type, each EL polymer is preferably intercalated separately into the inorganic matrix and then the separate composites are blended together, this being known herein as a ‘blend of composites’.

In both cases, the prepared composites are solution processesable, and dip-coating or spin-coating from alcoholic solutions can be used to form continuous, homogenous, EL thin films, which, if the components are correctly chosen, can be made to be either white-light emitting, or to emit at any preselected wavelength region within the limits allowed by the EL species used.

Confinement of the conjugated polymer chains within the spatially restrictive planar galleries of the layered matrix material is believed to provide molecular property benefits that can be exploited to promote controlled wavelength emission, whether white or of a preselected color. The layered matrix enforces an extended planar morphology conformation on the polymer monolayer, and at the same time, significantly reduces polymer aggregation and π-π interchain interactions including charge and energy transfer. Specifically, strong interactions between the conjugated molecular guest material and the semiconductor matrix sheets prevent the π-stacking of polymer chains. It is known that the π-π interactions are responsible for the efficient energy transfer in polymer films, owing to high inter-chain exciton hopping rates. Consequently, the reduced inter-chain interactions arising from the diminished π-stacking is expected to hinder the energy transfer between polymer chains accommodated within a single host grain or even within a single gallery. Therefore, even in the “composite of blends” type of nanocomposite, where energetic interaction may have been expected between different mixed polymer species incorporated within a single gallery, this mechanism appears to be effective in reducing such interaction, and in maintaining the essentially independent emission of each species. It is also possible that inhibited exciton diffusion is also achieved by reduction of the exciton life-time due to interactions with the matrix.

Although the explanations provided in the foregoing paragraph are believed to be an accurate representation for the independent emissive operation of a plurality of EL species incorporated within a host matrix, it is to be understood that these embodiments of the present invention are claimed as operative regardless as to whether these explanations are indeed accurate or not.

According to a further preferred embodiment of the present invention, an indirect semiconductor such as SnS₂ may preferably be used as the host matrix, such a material preserving its semiconducting properties after the exfoliation and restacking processes performed in the preparation of the EL material. In a device comprising the preferred polymer-incorporated SnS₂ composite as the active layer, injected carriers propagate along both the SnS₂ host and the conjugated polymer guest. Radiative charge recombination, on the other hand, takes place only in the polymer.

Although the invention is generally described in this application using SnS₂ as a preferred example of a host matrix material, it is to be understood that the invention is not meant to be limited to this material, but is meant to include any material or mixture of materials having semiconducting properties, which fulfill the necessary requirements of implementing this invention, including the preparation methods described hereinbelow. As previously indicated, insulating hosts may be used, but are likely to result in less efficient devices.

Several inorganic layered materials may preferably be used as the semiconductor hosts for conjugated polymers, including but not limited to, metal dichalcogenides such as SnS₂, WSe₂; metal monochalcogenides such as InSe, GaS; metal halides such as PbI₂, CdI₂; and metal oxides such as: V₂O₅, MoO₃. Inorganic isolating layered materials for mixing with the semiconducting material include, but are not limited to, layered silicates and layered metal oxides.

There is thus provided in accordance with a preferred embodiment of the present invention, an electroluminescent composite material comprising:

(i) at least two light-emitting polymers, each of the polymers emitting light over different wavelength ranges, and
(ii) a layered inorganic host,
wherein the at least two of light-emitting polymers are intercalated between layers of the host, such that the luminescent composite material emits a combination of the light emitted by the at least two polymers over the different wavelength ranges.

In the above mentioned luminescent composite material, the ratio of the at least two light-emitting polymers is preferably selected such that the combination of the light emitted by the polymers over the different wavelength ranges generates white light. The at least two light-emitting polymers may preferably be three light emitting polymers whose emission is located in the red, green and blue regions of the spectrum. According to further preferred embodiments, the ratio of the at least two light-emitting polymers may be selected such that the combination of the light emitted by the polymers over the different wavelength ranges generates light of a predetermined wavelength.

There is further provided in accordance with yet another preferred embodiment of the present invention, a luminescent composite material as described above, and wherein the layered inorganic host comprises any one of a layered semiconductor material and a layered semiconductor material blended with an insulator.

Any of the above described luminescent composite materials may preferably comprise a mixture of the at least two light-emitting polymers intercalated between the layers of the inorganic host.

Alternatively and preferably, any of the above described luminescent composite materials may comprises a mixture of two portions of the layered host material, each of the portions comprising the inorganic host having one of the at least two light-emitting polymers intercalated between its layers.

In accordance with still more preferred embodiments of the present invention, in any of the luminescent composite materials described hereinabove, the inorganic host is selected from the group consisting of semiconducting layered metal dichalcogenides, metal monochalcogenides, metal halides and metal oxides, and blends thereof with insulating layered metal dichalcogenides, metal monochalcogenides and metal oxides.

Furthermore, in any of the luminescent composite materials described hereinabove, the light-emitting polymers are preferably any one of light-emitting conjugated polymers, light-emitting non-conjugated polymers, organic low-molecular weight light-emitting materials, or copolymers of the materials. In such a case, if the light-emitting polymers are conjugated polymers, they may preferably comprise at least one of poly(p-phenylenevinylene) and its derivatives, polythiophene and its derivatives, poly(p-phenylene) and its derivatives, polyfluorene and its derivatives, polyquinoline and its derivatives, polyacetylene and its derivatives, and polypyrrole and its derivatives. If the light-emitting polymers are non-conjugated polymers, they are preferably poly(9-vinylcarbarzole) or its derivatives.

There is further provided in accordance with still another preferred embodiment of the present invention, an electroluminescent device, comprising in the following spatial order:

(i) a substrate,
(ii) a first electrode deposited over the substrate,
(iii) a luminescent layer, and
(iv) a second electrode,
wherein the luminescent layer comprises a luminescent composite material according to any of the embodiments described hereinabove.

In accordance with an even further preferred embodiment of the present invention, there is also provided an electroluminescent device, comprising in the following spatial order:

(i) a substrate,
(ii) a first electrode deposited over the substrate,
(iii) at least two luminescent layers, and
(iv) a second electrode,
wherein the at least two luminescent layers comprise:
(a) at least one layer of a luminescent composite material according to any of the embodiments described hereinabove, and
(b) at least one layer of a non-composite light-emitting polymer.

In either of the two above-mentioned electroluminescent devices, the substrate is preferably any one of glass, quartz, and PET (polyethylene terephtalate). Furthermore, the first electrode is preferably selected from the group consisting of ITO (indium tin oxide), zinc-doped indium oxide (IZO), indium oxide, tin oxide and zinc oxide, PEDOT (polyethylene dioxythiophene), and polyaniline. Additionally, the metal electrode is preferably selected from the group consisting of aluminum, magnesium, lithium, calcium, copper, gold, potassium, sodium, lanthanum, cerium, strontium, barium, silver, indium, tin, zinc, zirconium, and binary or ternary alloys containing combinations of these metals.

There is also provided in accordance with a further preferred embodiment of the present invention, an electroluminescent device as described above, further comprising a hole transporting layer formed between the first electrode and the luminescent layer. Alternatively and preferably, in those electroluminescent devices having at least two luminescent layers, the hole transporting layer may be formed between the first electrode and the at least two luminescent layers. In either of these two cases, the hole transporting layer is preferably composed of one or more materials which are selected from the group consisting of polymers including polyvinylcarbazole and its derivatives, organic low-molecular materials including 4,4′-dicarbazolyl-1,1′-biphenyl-(CBP), TPD(N,N′-diphenyl-N,N′-bis-(3-methylphenyl)-1,1′-biphenyl-4,4′-diam-ine), NPB(4,4′-bis[N-(1-naphthyl-1-)-N-phenyl-amino]-biphenyl), triarylamine, pyrazoline and their derivatives, and organic low-molecular and polymer materials containing a hole transporting moiety.

There is also provided in accordance with another preferred embodiment of the present invention, an electroluminescent device as described above, further comprising an electron transporting layer formed between the luminescent layer and the second electrode. Alternatively and preferably, in those electroluminescent devices having at least two luminescent layers, the electron transporting layer may be formed between the at least two luminescent layers and the second electrode. In either of these two cases, the electron transporting layer is preferably composed of one or more materials which are selected from the group consisting of TPBI(2,2′,2′-(1,3,5-phenylene)-tris[1-phenyl-1H-benzimidaz-ole]), poly(phenyl quinoxzline), 1,3,5-tris[(6,7-dimethyl-3-phenyl)quinoxa-line-2-yl]benzene(Me-TPQ), polyquinoline, tris(8-hydroxy quinoline)aluminum(Alq3), {6-N,N-diethylamino-1-methyl-3-phenyl-1H-pyrazo-lo[3,4-b]quinoline}(PAQ-Net2), and low-molecular weight and polymer materials containing an electron transporting moiety.

There is further provided in accordance with yet another preferred embodiment of the present invention, a method of providing luminescent emission at a predetermined wavelength, comprising the steps of:

(i) determining the chromaticity co-ordinates of the predetermined wavelength on a chromaticity diagram,
(ii) providing a luminescent composite material comprising a pair of light-emitting polymers selected such that a straight line connecting the color co-ordinates of their emission on the chromaticity diagram passes through the region of the predetermined wavelength,
(iii) determining the relationship between the ratio of the light emitting polymers in the luminescent composite material and the emission color along the connecting line for a limited number of the ratios, and
(iv) using the relationship to select the ratio of the light-emitting polymers, such that the luminescent emission obtained is that of the predetermined wavelength,
wherein the luminescent composite material further comprises a layered inorganic host matrix, between whose layers the two light-emitting polymers are intercalated.

In accordance with still another preferred embodiment of the present invention, there is also provided a method of providing luminescent emission at a predetermined wavelength, comprising the steps of:

(i) determining the chromaticity co-ordinates of the predetermined wavelength on a chromaticity diagram,
(ii) providing a luminescent composite material comprising three light-emitting polymers selected such that the chromaticity co-ordinates of the predetermined wavelength falls within a triangle having the three colors at its apices,
(iii) determining the relationship between the ratio of the light emitting polymers in the luminescent composite material and the emission color along the connecting line for a limited number of the ratios, and
(iv) determining the relationship between the ratio of the light emitting polymers in the luminescent composite material and the emission color within the triangle for a limited number of the ratios, and
(v) using the relationship to select the ratio of the light-emitting polymers, such that the luminescent emission obtained is that of the predetermined wavelength,
wherein the luminescent composite material further comprises a layered inorganic host matrix, between whose layers the light-emitting polymers are intercalated.

There is further provided in accordance with still another preferred embodiment of the present invention, a method of preparing a luminescent nanocomposite material, comprising:

(i) providing at least two light-emitting polymers, each of the polymers emitting light over different wavelength ranges,
(ii) providing a layered inorganic host, and
(iii) intercalating the at least two light-emitting polymers between layers of the layered inorganic host.

In this method, the intercalating step preferably comprises the steps of:

(i) producing an alkali metal intercalated compound of the layered inorganic host,
(ii) exfoliating the alkali metal intercalated compound of the inorganic host in a first solvent to generate a suspension,
(iii) mixing the light emitting polymers in a second solvent compatible with the first solvent, to generate a solution,
(iv) mixing the suspension and the solution to produce a flocculated composite material of the light emitting polymers intercalated into the layered inorganic host, and
(v) washing the flocculated composite material with an organic solvent to remove traces of non-intercalated polymer.

In this method, the alkali metal is preferably selected from a group consisting of lithium, sodium and potassium, and the first solvent is preferably selected from a group consisting of water, an alcohol and a combination of them. Additionally, the second solvent is preferably selected from a group consisting of dichloromethane, chloroform, benzene, toluene, xylene, anisole, cresol, nitrobenzene, dichlorobenzene, tetrahydrofuran, dimethoxyethane, N,N-dimethylformamide, N,N-dimethylacetamide, N-methylpyrrolidone, and the organic solvent is preferably selected from a group consisting of dichloromethane, chloroform, benzene, toluene, xylene, anisole, cresol, nitrobenzene, dichlorobenzene, tetrahydrofuran, dimethoxyethane, N,N-dimethylformamide, N,N-dimethylacetamide, N-methylpyrrolidone.

Furthermore, in any of these above methods of preparing a luminescent nanocomposite material, the layered inorganic host may preferably comprise a semiconductor material. Additionally, the inorganic host may preferably be selected from the group consisting of semiconducting layered metal dichalcogenides, metal monochalcogenides, metal halides and metal oxides, and blends thereof with insulating layered metal dichalcogenides, metal monochalcogenides and metal oxides.

In accordance with a further preferred embodiment of the present invention, there is also provided a method of preparing a luminescent nanocomposite material, comprising:

(i) providing at least two light-emitting polymers, each of the polymers emitting light over different wavelength ranges,
(ii) providing a layered inorganic host,
(iii) intercalating a first one of the at least two light-emitting polymers between layers of a layered inorganic host to produce a first nanocomposite,
(iv) intercalating a second one of the at least two light-emitting polymers between layers of the layered inorganic host to produce a second nanocomposite, and
(v) mixing the first nanocomposite and the second nanocomposite.

In this method, each of the steps of intercalating of the first and the second ones of the at least two light-emitting polymers preferably comprises the steps of:

(i) producing an alkali metal intercalated compound of the layered inorganic host,
(ii) exfoliating the alkali metal intercalated compound of the inorganic host in a first solvent to generate a suspension,
(iii) mixing a solution of that light emitting polymer associated with the intercalation step being performed in a second solvent compatible with the first solvent, to generate a solution,
(iv) mixing the suspension and the solution to produce a flocculated composite material of the light emitting polymer associated with that intercalation step, intercalated into the layered inorganic host, and
(v) washing the flocculated composite material with an organic solvent to remove traces of non-intercalated polymer.

In this method, the alkali metal is preferably selected from a group consisting of lithium, sodium and potassium, and the first solvent is preferably selected from a group consisting of water, an alcohol and a combination of them. Additionally, the second solvent is preferably selected from a group consisting of dichloromethane, chloroform, benzene, toluene, xylene, anisole, cresol, nitrobenzene, dichlorobenzene, tetrahydrofuran, dimethoxyethane, N,N-dimethylformamide, N,N-dimethylacetamide, N-methylpyrrolidone, and the organic solvent is preferably selected from a group consisting of dichloromethane, chloroform, benzene, toluene, xylene, anisole, cresol, nitrobenzene, dichlorobenzene, tetrahydrofuran, dimethoxyethane, N,N-dimethylformamide, N,N-dimethylacetamide, N-methylpyrrolidone.

Furthermore, in any of these above methods of preparing a luminescent nanocomposite material, the layered inorganic host may preferably comprise a semiconductor material. Additionally, the inorganic host may preferably be selected from the group consisting of semiconducting layered metal dichalcogenides, metal monochalcogenides, metal halides and metal oxides, and blends thereof with insulating layered metal dichalcogenides, metal monochalcogenides and metal oxides.

### BRIEF DESCRIPTION OF THE DRAWINGS

The present invention will be understood and appreciated more fully from the following detailed description, taken in conjunction with the drawings in which:

FIG. 1A, illustrates schematically an example of an inorganic layered host matrix, in the form of a dichalcogenide layer-type structure;

FIG. 1B depicts a polymeric species intercalated into the layered host matrix material;

FIGS. 2A to 2C illustrate schematically the various stages of a method of intercalating a polymer EL active species into a layered matrix host, according to a preferred embodiment of the present invention;

FIGS. 3 and 4 illustrate schematically two different types of nanocomposites of mixtures of active EL species, FIG. 3 showing a “composite of blends” material, while FIG. 4 shows a “blend of composites” material;

FIG. 5 shows a typical graph of the optical absorption spectra of each of three RGB polymers;

FIG. 6 shows the equivalent photoluminescence spectra of each of the three polymers of FIG. 5;

FIG. 7 shows the photoluminescence spectra of a simple blend of the three RGB polymers of FIGS. 5 and 6;

FIG. 8 shows the photoluminescence spectra obtained when the mixture of RGB polymers of FIGS. 5 and 6 are incorporated into a layered SnS₂ matrix, according to the various embodiments of the present invention;

FIG. 9 shows a chromaticity plot in the form of a CIE diagram, used to illustrate the color tuning of nanocomposites to a predetermined wavelength region, using materials and methods according to further preferred embodiments of the present invention;

FIG. 10 shows a schematic cross-sectional view of an electroluminescent device, constructed and operable according to further preferred embodiments of the present invention;

FIG. 11 shows the electroluminescence output spectrum from a device of the type shown in FIG. 10;

FIG. 12 is a graph showing the current-voltage-luminance characteristics of a device of the type shown in FIG. 10;

FIG. 13 is a schematic cross-sectional view of a further electroluminescent device, constructed and operable according to further preferred embodiments of the present invention;

FIG. 14 shows the photoluminescence spectra obtained from the emitting material of the device of the type shown in FIG. 13;

FIG. 15 is a schematic cross-sectional view of an electroluminescent device, fabricated with multiple layers of polymer emitters, according to yet a further preferred embodiment of the present invention;

FIG. 16 shows the photoluminescence spectra of the multilayer films used in the device of the embodiment of FIG. 15, when excited at 380 nm;

FIG. 17 shows the electroluminescence output spectrum from a device of the type shown in FIG. 15;

FIG. 18 is a graph showing the current-voltage-luminance characteristics of a device of the type shown in FIG. 15;

FIG. 19 illustrates X-ray diffraction measurements supporting the mechanisms proposed regarding the generation of the EL emission by the methods of the present invention; and

FIG. 20 shows photoluminescence spectra of the materials whose XRD plots are shown in FIG. 19.

### DETAILED DESCRIPTION OF PREFERRED EMBODIMENTS

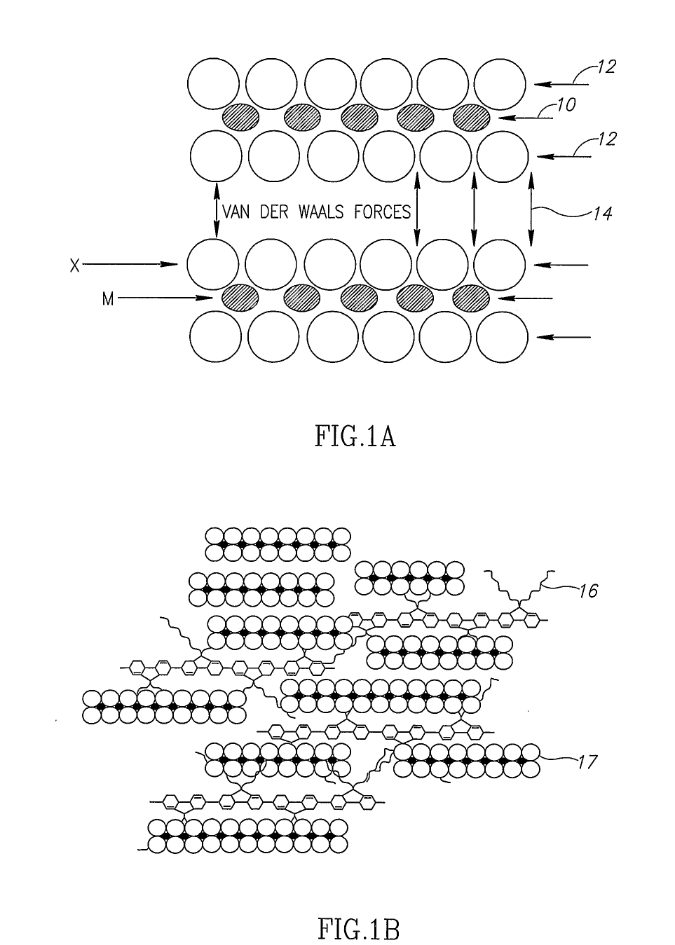

Reference is now made to FIG. 1A, which illustrates schematically an example of an inorganic layered host matrix, suitable for incorporating the active organic EL materials used in the present invention. The matrix comprises metal atoms and chalcogen atoms, and is shown in FIG. 1A as a dichalcogenide layer-type structure, though layered metal monochalcogenides may also be used. The layered metal dichalcogenides may have the chemical formula MX₂ wherein M represents a metal and X represents a chalcogen, such as oxygen, sulfur, selenium or tellurium. The structure of the layered metal dichalcogenides preferably includes one sheet 10 of metal atoms sandwiched between two sheets 12 of chalcogen atoms. In the layered metal dichalcogenides, the metallic component M is preferably selected from the transition metals such as titanium, zirconium, hafnium, vanadium, tantalum, niobium, molybdenum and tungsten or some non-transition metals, preferably tin. More preferred chalcogens are sulfur and selenium. Metals that form monochalcogenides which may be suitable include gallium, indium and thallium.

In the layered metal dichalcogenides, the metallic sheet is generally covalently bonded to the two adjacent sheets of chalcogens, while adjacent MX₂ layers are kept together by Van der Waals forces 14, which are known to be weak forces. This structure leads to very anisotropic mechanical, chemical and electrical properties, in which the interlayer space can be separated considerably to incorporate guest species, such as polymer EL active materials, while preserving the integrity of the layer structure. FIG. 1B depicts a polymeric species 16 intercalated into the layered matrix material 17. It is observed that each layer can contain only a single polymer chain as a monolayer, with the concomitant advantages of highly reduced interaction between separate chains, as previously described. In this exemplary schematic illustration, the polymer shown is a blue light emitting polymer. A particular advantage of the use of such layered materials, is that they and their intercalated products can be processed simply and cheaply using chemical processes, and then to produce thin films by conventional procedures for use in devices.

The electronic properties of the layered metal chalcogenides vary widely, including semiconductors, semi-metals and true metals. The resistivity of the layered metal chalcogenides ranges from very low values such as approximately 4×10⁻⁴ Ω-cm for niobium diselenide and tantalum disulfide to values such as 10 Ω-cm in molybdenum disulfide. Clearly, in order to function as an efficient host in the active layer of a diode, it is important that the conductivity of the layered metal chalcogenides is sufficiently high to enable charge transport. The optimum choice for use as polymer hosts in organic EL devices are semiconducting layered metal chalcogenides.

One of two strategies has been previously used for the intercalation of conjugated polymers into layered hosts: i) delaminating of the inorganic layers (exfoliation) followed by their restacking with the polymer incorporated between the layers; and ii) intercalation of monomers followed by in-situ polymerization. The latter method is generally limited to a small number of monomers which could undergo appropriate polymerization processes to yield the conjugated polymer. The former is limited to conductive polymers which could be mixed with the polar solution of the delaminated inorganic layers. Semiconducting polymers, on the other hand, are insoluble in polar solvents and the addition of a polymer solution into the polar single-layer suspension results in an undesirable macroscopic phase separation. Organically modified silicate layers are soluble in hydrophobic solvents and hence could be homogenously mixed with the semiconducting polymer solutions. Sedimentation of the layers incorporates some of the polymer chains in between the layers while leaving a considerable amount of the polymer chains non-intercalated. The polymer excess can not be washed away because both the polymer and the modified host are soluble in the same solvents. In these nanocomposite materials, excitons formed on incorporated polymer chains have short diffusion lengths, but the diffusion of excitons formed on non-incorporated polymer segments will not be affected, and will result in degradation both of white light emission, and of the generation of a predetermined color by mixing of separate color emissions. For the generation of either of these types of emission, it is necessary to inhibit all exciton diffusion, and hence, the complete incorporation of the polymer chains in the matrix appears to be a mandatory step in the exfoliation and restacking methods of preparation of the active materials.

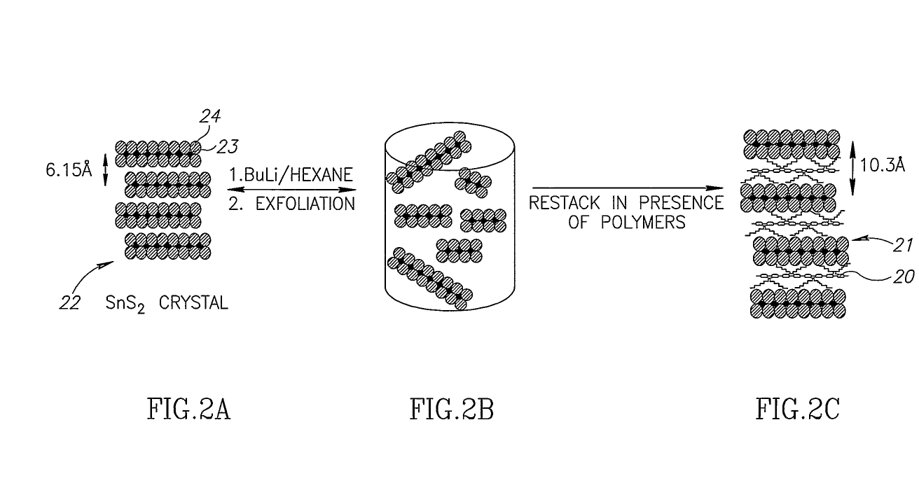

Reference is now made to FIGS. 2A to 2C, which schematically illustrate a method of intercalating a polymer EL active species 20 into the layered matrix host 21, according to a preferred embodiment of the present invention. The host used to illustrate the process is a layered SnS₂ structure. In FIG. 2A is schematically shown a layered SnS₂ structure 22, derived from hexagonal sheets of tin atoms 23, sandwiched between two hexagonal sheets of sulfur atoms 24. As shown in FIG. 1, the S—Sn—S sheets themselves are covalently bonded, while adjacent SnS₂ layers interact via Van-der Waals forces. FIG. 2B illustrates schematically the exfoliation of micron-size SnS₂ particles. This may be preferably performed in methanol, to form a single layer suspension, though any other suitable solvent may be used. The procedure of Murphy et. al. (D. W. Murphy, F. J. Di Salvo, G. W. Hull, and V. Waszczak, Inorg. Chem. 1976, 15, 17) is preferably used, in which LiₓSnS₂ is prepared by addition of BuLi (1.6 M in hexanes) to SnS₂ powder under a nitrogen atmosphere. In a typical exemplary process, 40-50 mg of LiₓSnS₂ are then exfoliated in 7 ml. of methanol in an ultrasonic bath for 60 minutes. The suspension is centrifuged and the sediment subsequently redispersed in methanol. This process is preferably repeated a number of times to ensure full removal of Li ions. This is followed by direct mixing of the slurry with a solution, preferably of xylene, containing the polymer(s) to be intercalated, and mixing of the solution typically for 4 days. Other solvents compatible with the exfoliation process solvent may be used.

The result of such a preparation procedure is shown in FIG. 2C which illustrates schematically how the presence of the conjugated polymer species induces flocculation of the SnS₂ sheets, effectively isolating the separate polymer molecules within the reassembled SnS₂ inter-layer galleries. It is noted that the intercalation of the polymer chains 20 has increased the inter-layer distance to 10.3 Å, this being enabled because of the nature of the Van der Waals force between the layers. According to the methods of this preferred embodiment of the present invention, the restacked conjugated polymer/SnS₂ products are preferably washed with organic solvents a number of times, a procedure not generally being mentioned in descriptions of the preparation of prior art clay/polymer nanocomposites. This procedure ensures removal of non-incorporated polymer species, while maintaining the integrity of the polymer-intercalated layered nanocomposite structure. The resulting powders are preferably washed in xylene until no traces of polymers are detected in the absorption spectra of the supernatant wash solutions, to ensure that all remaining polymer species are indeed confined in the galleries of the host matrix. Thin continuous and homogenous films of the intercalated SnS₂ nanocomposites can be prepared by re-dispersing the plate-like powder particles in xylene, followed by drop-casting or spin-coating.

The incorporation of the polymer species within the host matrix as completely as possible, and the removal of non-incorporated species as thoroughly as possible, are important aspects of the present invention and of the method of preparation of the emissive materials used therein. These steps ensure optimum inhibition of exciton diffusion, and hence optimize the generation of pure white light, or of any desired color made up of predetermined mixtures of independent emissions. The importance of this feature may not be apparent from prior art use of nanolayer hosts, such as that described by J. H. Park et al, in their above mentioned article, where it is stated only that “a considerable number of PDOF molecules were isolated within the 2-D lamellar structure.”

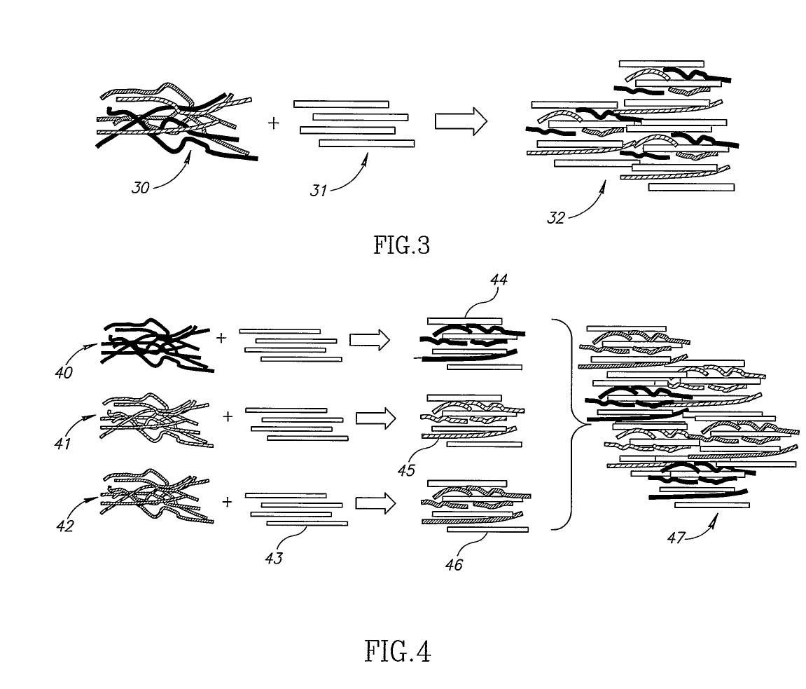

Reference is now made to FIGS. 3 and 4 which illustrate schematically the two different types of nanocomposites of mixtures of active EL species, using 3 species as an example. These 3 species may preferably be red, blue and green emitting polymers, to enable either white or essentially any ultimate color to be generated. In FIG. 3, there is shown the intercalation of a polymer blend of the three EL components 30 into the inorganic layered matrix 31, resulting in a layered structure 32 containing a mixture of the three polymer species, this having been called the “composite of blends” type of nanocomposite. In FIG. 4, there is shown the intercalation of each of the three polymer species 40, 41, 42, separately into the host structures 43, to generate three separate monochromatic nanocomposites, one for each polymeric species 44, 45, 46. The three monochromatic nanocomposite powders are then mixed to produce the second type of nanocomposite 47, previously called the “blend of composites” type of nanaocomposite.

According to preferred embodiments of the present invention, the blue, green and red EL emitting species may preferably be:

Blue—poly(9,9-dioctylfluorenyl-2,7-diyl) (PFO)
Green—poly(9,9-dioctylfluorenyl-2,7-diyl)-co-1,4-benzo-(2,1′,3)-thiadiazole) (F8BT)
Red—poly[2-methoxy-5(2′-ethyl-hexyloxy)-1,4-phenylenevinylene] (MEH-PPV)

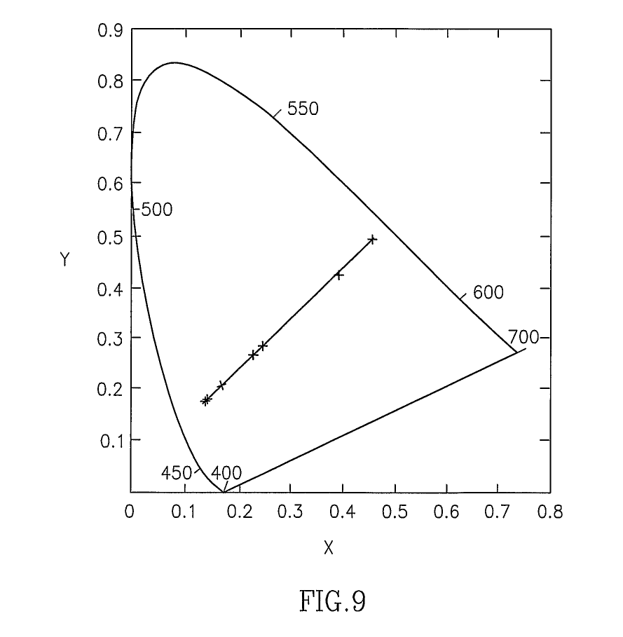

The use of these three RGB polymers in order to prepare a white light emitting nanocomposite involves dissolution in o-xylene. For the ‘composite of blends’ applications, a polymer-blend using a ratio of 30B/60G/10R wt % may preferably be used. For the ‘blend of composites’ films, powders of SnS₂ intercalated with each of the RGB polymers at ratios of 30B/65G/5R wt % may preferably be used. The method by which the ratio is calculated for preparing nanocomposites having a specific preselected color is described hereinbelow, in relation to the preferred embodiment illustrated by FIG. 9.

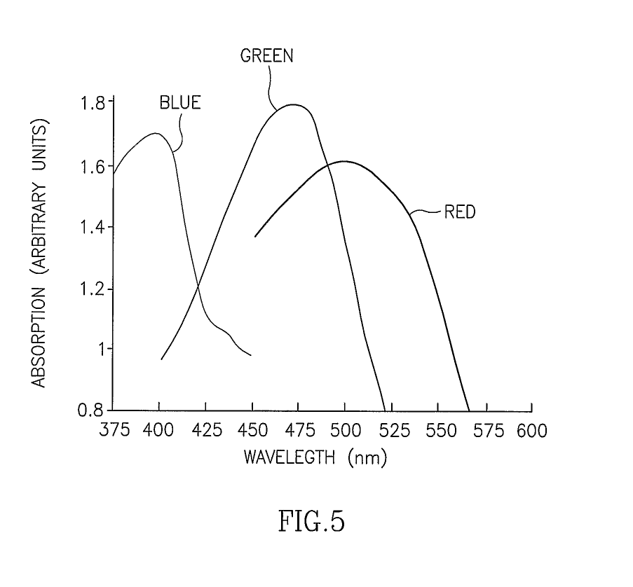

Reference is now made to FIG. 5, which shows a typical graph of the optical absorption spectra of each of the three above-mentioned RGB polymers.

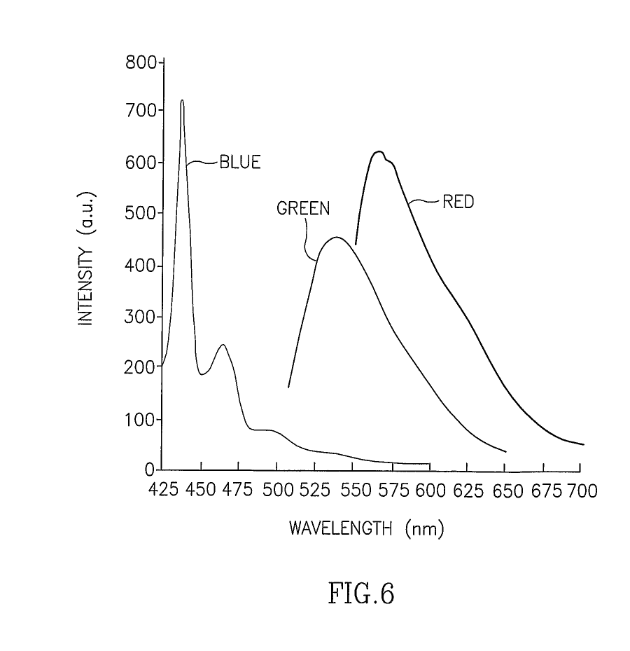

FIG. 6 shows, for comparison, the equivalent photoluminescence spectra of each of the three polymers of FIG. 5.

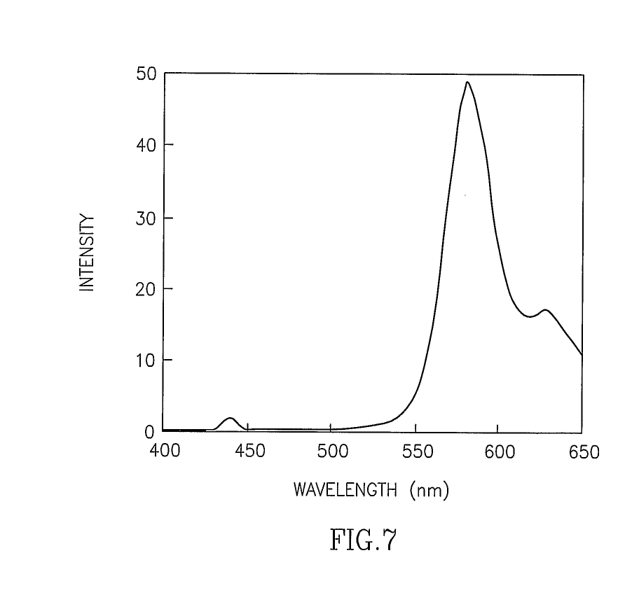

Reference is now made to FIG. 7, which shows the photoluminescence spectra of a simple blend of the three RGB polymers of FIGS. 5 and 6, with a percentage weight ratio of 31/61/8 for the Blue/Green/Red polymers. The excitation wavelength used to generate this photoluminescence result is 380 nm. This graph shows the prior art results of simple mixing of the three species, without incorporation within a layered host matrix. As is observed, the energy is funneled to the emissive moiety with the lowest gap, namely the Red species, resulting in light emission dominated by the polymer with the longest emission wavelength, in the Red.

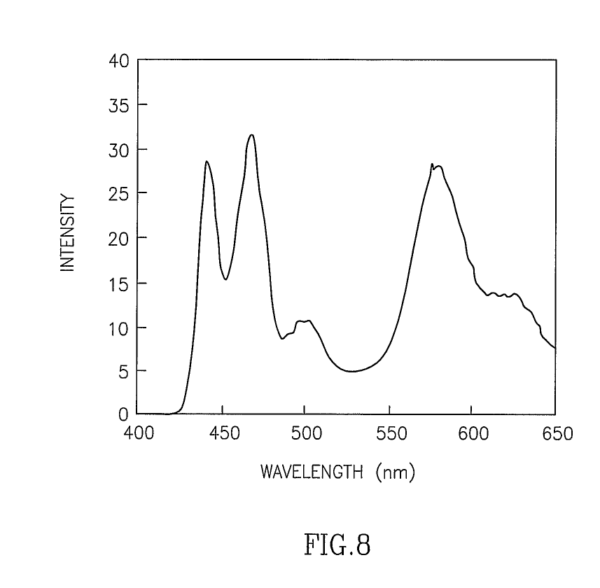

Reference is now made to FIG. 8, which, in contrast to the results shown in FIG. 7, shows the photoluminescence spectra obtained when the mixture of RGB polymers are incorporated into a layered SnS₂ matrix, according to the various embodiments of the present invention. The excitation wavelength is again 380 nm. As is observed by this graph, the SnS₂ layered structure effectively separates the different light emitting polymers, thus inhibiting energy transfer therebetween, and maintaining the independent output wavelengths of each. The percentages of these emitters can then be mixed in the ratio required to generate the desired output spectrum from the polymer mixture, using emission from all three of the chromophores to generate a white output.

Reference is now made to FIG. 9, which shows a chromaticity plot in the form of a CIE diagram, used to illustrate the color tuning of nanocomposites to a predetermined wavelength region, using materials and methods according to further preferred embodiments of the present invention. Although the results plotted in FIG. 9 were obtained using the second type of nanocomposites, the “blend of composites”, the method obtained therefrom is equally applicable to the first type of nanocomposites, the “composite of blends”. Additionally, although the results plotted in FIG. 9 were obtained from photoluminescent measurements, which are simple to perform, it is to be understood that the same considerations would be applicable to a device constructed to emit electroluminescence and to be color tunable by selection of the active polymer species used therein. In order to obtain the results shown in FIG. 9, separate nanocomposites of blue- and red-emitting polymers were prepared, and the monochromatic composites were then mixed in different compositions. The chromaticity coordinates denoting the color emitted by each mixture were calculated, and marked on the CIE diagram. Points 1 and 6 indicate the coordinates of the monochromatic nanocomposites, point 1 being the blue emitter and point 6 the red emitter. Points 2-5 denote different mixtures of the monochromatic nanocomposites. All the mixture points fall accurately, within the limits of experimental error, on a straight line connecting the points associated with the separate monochromatic species, this indicating that there is no energy transfer between the components.

In order to tune the color of the emission of a device constructed using mixtures of these two species within one of the above-described nanocomposite schemes, it is necessary first to determine the position of the desired color on the chromaticity diagram. Then, two light-emitting polymers are selected from the wide range of available materials, such that a connecting line constructed through their color co-ordinates passes through the region of the co-ordinates of the desired wavelength on the chromaticity diagram. An initial calibrating procedure is performed, to determine how the ratio of the two light-emitting polymers affects the color obtained along the connecting line, and from this preliminary experimental determination, the correct ratio for the desired color can be readily calculated or determined from a look-up table. For many situations, it is expected that the position of any point on the connecting line may be related in a linear manner to the ratio of the two chromophores whose colors make up the end points of the connecting line. In such a case, the correct ratio of the mixture of emitting polymer species to provide the desired color along the connecting line can be simply calculated by assuming this linear relation. Whatever method is applicable, according to this preferred embodiment of the present invention, device tunability, which, according to the methods of the prior art, previously required laborious efforts based on much trial and error experimentation, can be simply achieved by calculating from the premeasured characteristics of the polymer emitters used, the correct mixture ratio to provide emission at any desired color, primary or secondary.

In order to explain the operation of this aspect of the present invention in a simple manner, a mixture of only two emitters has been used in FIG. 9. It is to be understood that using 2 chromophores, only colors whose co-ordinates are situated on the connecting line between the co-ordinates of these two chromophores can be obtained. If, in spite of the wide range of electroluminescent chromophores available commercially through the versatility of polymer chemistry, it is not found possible to obtain a connecting line running through the exact color desired (this being a not unusual situation), then a mixture of three chromophores is used, as indeed described in the various other embodiments of the present invention throughout this application. It is well known in the art how to manipulate mixtures of three colors to generate any color within the triangle formed with the co-ordinates of these three colors at its apices. Using these methods, the selection of a mixture of three different emitters to produce electroluminescent emission at any desired secondary color, according to the methods of the present invention, can be readily achieved.

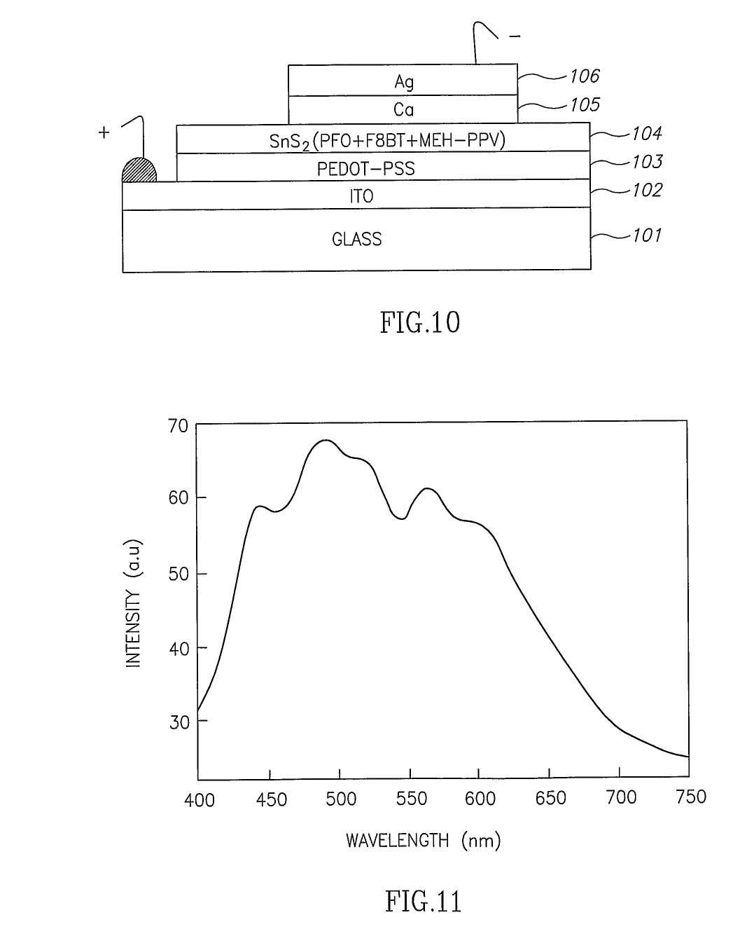

Reference is now made to FIG. 10, which shows a schematic cross-sectional view of an electroluminescent device, constructed and operable according to further preferred embodiments of the present invention. In the device of FIG. 10, the light emitting layer is formed of a type 1 “composite of blends” nanocomposite, in which the polymers are blended in one solution; the tin sulfide matrix material is added and the nanocomposite solution is applied by any of the methods known in the art, at the appropriate layer in the device, on top of the Indium Tin Oxide electrode layer, in accordance with the present invention.

According to another preferred embodiment of the present invention, a method of fabricating the device of FIG. 10, from which the structure of the device can also be understood, comprises the steps of:

1. Coating a glass substrate 101 with a transparent electrode 102, such as Indium tin oxide (ITO). Alternatively and preferably, other transparent electrode materials may be used.
2. The ITO layer is optionally coated with a hole injection layer 103. PEDOT-PSS, which is Poly(3,4-ethylenedioxythiophene) poly(styrenesulfonate), may preferably be used. It is a water suspension with 2 polymers in it, one of which is conjugated (PEDOT) and the other of which is an acidic polymer PSS. PEDOT:PSS is used for hole injection due to its high work function. However, it also has the important effect of smoothing the ITO surface. A 100 nm layer of PEDOT:PSS is preferably spin coated onto the ITO electrode, preferably followed by a 200° C. heat treatment for 2 hours under inert conditions.
3. The light-emitting nanocomposite is preferably prepared by mixing the polymer emitters in a single solution, followed by addition of the matrix material. The matrix is prepared by commencing with commercially available layered material powders, intercalating them with Li, and exfoliating in methanol to form a single-layer suspension in methanol, as previously described. This suspension is then added to the polymer solution and the host and polymer interact to form the layered organic/inorganic structures described hereinabove. The resulting solution is thoroughly washed, preferably in a solvent such as xylene, in order to remove as much as possible of the un-intercalated polymer.
4. The light-emitting layer itself 104, typically having a thickness of the order of 1,500 nm, is prepared by any one of several methods, including spinning, dropping, casting or any other suitable technique used for film deposition.
5. The light emitting layer is optionally coated with an electron injection layer 105, for example, Calcium which acts as the cathode of the device.
6. The electron injection layer is coated with a metal electrode layer 106, such as Gold (Au). However, other metals such as Ag, Al, Cu, or Pt may also be used. A Ag or Al layer is preferably evaporated to protect the Ca electron injection layer from oxidation. Typically used thicknesses are 50 nm of Ca protected by 250 nm of Ag, over a pixel size of 1×3 mm.

An electric voltage is applied between the ITO and cathode protection electrode to operate the device.

Reference is now made to FIG. 11, which shows the electroluminescence output spectrum from a device of the type shown in FIG. 10, fabricated with a white-emitting SnS₂ active layer incorporating a blend of PFO, F8BT and MEH-PPV polymers. As can be clearly seen from the graph, a wide spectrum of light is emitted, demonstrating the inhibition of energy transfer among the different polymers, and the generation of a white light output.

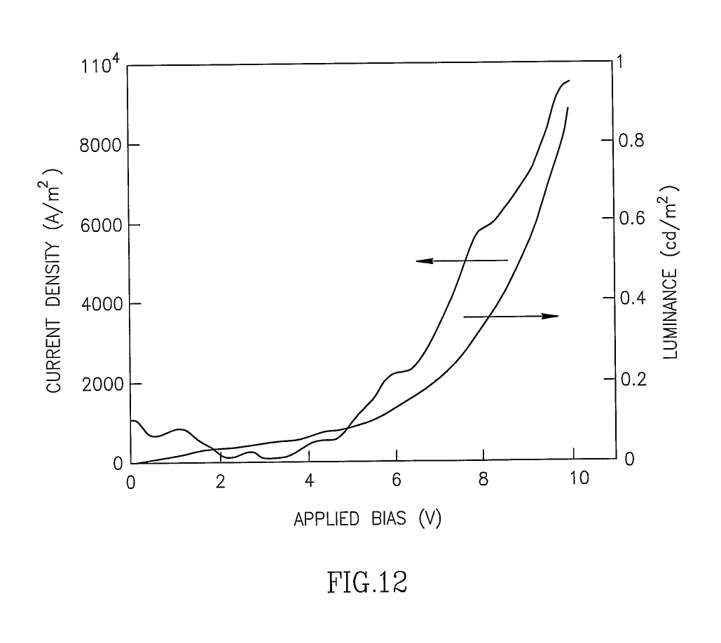

Reference is now made to FIG. 12, which is a graph showing the current-voltage-luminance characteristics of a device of the type shown in FIG. 10.

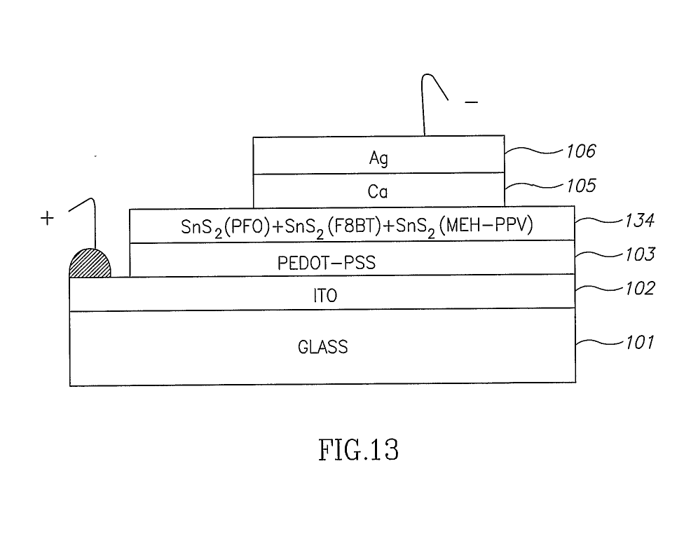

Reference is now made to FIG. 13, which is a schematic cross-sectional view of a further electroluminescent device, constructed and operable according to further preferred embodiments of the present invention. The device of FIG. 13 is similar to that shown in FIG. 10, and the various structural layers are labeled identically to those of FIG. 10, except that the light emitting layer 134 is formed of a type 2 “blend of composites” nanocomposite, in which each of the polymers is incorporated into its own separate nanocomposite by addition of the matrix material, and the three separate polymer intercalated matrices are blended together in one solution to form the active nanocomposite for the device, which is then spun or otherwise applied as the light emitting layer in accordance with the preferred methods of the present invention.

The method of fabricating the device of FIG. 13 is generally identical to that described in connection with FIG. 10, except that the preparation of the light emitting material preferably comprises the step of:

3. Dissolving each of the polymers in a separate solution, and adding each polymer solution to a single layer suspension of the matrix. Each mixture is then dried to form powders of a single type of polymer intercalated in the matrix. Each of the powders is then preferably mixed in the desired ratio, and the mixture suspended in methanol or ethanol, to obtain a blend of composites that emits the desired color, whether white-light, or another preselected color.

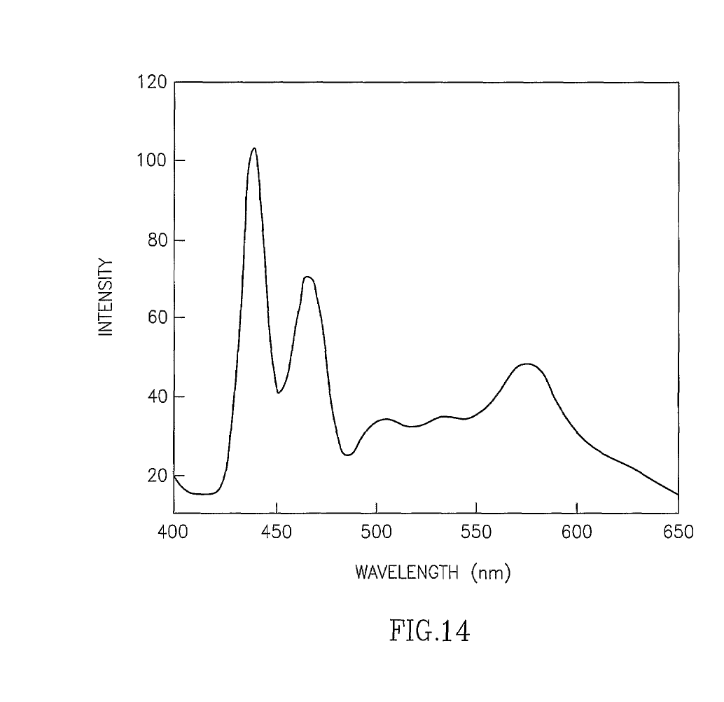

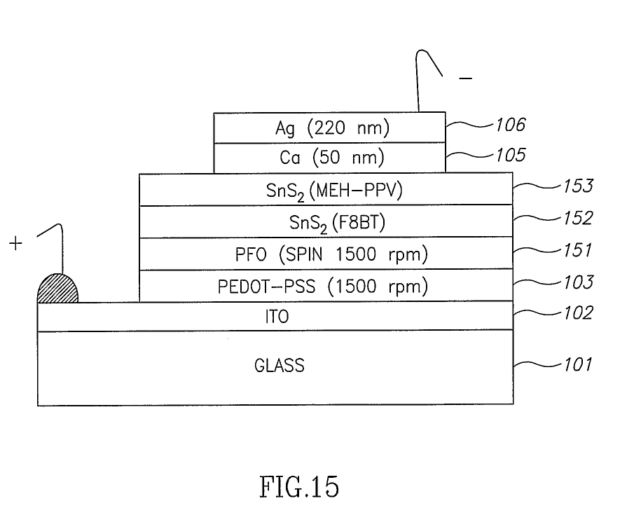

Reference is now made to FIG. 14, which shows the photoluminescence spectra obtained from the emitting material of the device of the type shown in FIG. 13, fabricated with a layer of white-emitting mixture of three SnS₂ nanocomposites, incorporating respectively PFO, F8BT and MEH-PPV polymers. The excitation wavelength is 380 nm. As is observed by this graph, the “blend of composite” layered structure, in a similar manner to that shown by the PL characteristics of the “composite of blend” material shown in FIG. 8, effectively separates the different light emitting polymers, thus inhibiting energy transfer therebetween, maintaining the independent output wavelengths of each, and enabling the generation of white light, or of a preselected color, from the device of FIG. 13.

Reference is now made to FIG. 15, which is a schematic cross-sectional view of an electroluminescent device, constructed and operable according to yet a further preferred embodiment of the present invention. The device of FIG. 15 is a multilayer electroluminescent device, similar to those shown in FIGS. 10 and 13, with the exception that the light emitting layer comprises at least two stacked layers, at least one of the layers being a nanocomposite layer, comprising an emitting polymer incorporated into a layered host matrix, and at least another one of the layers being an emitting polymer layer not incorporated into a matrix. In the preferred example of FIG. 15, three such layers are shown, two of which 152, 153, are nanocomposite layers respectively of MEH-PPV in a SnS₂ host matrix, and of F8BT in a SnS₂ host matrix, and the third 151 being a raw polymer layer of PFO active material. However, devices with two layers can also be constructed according to this embodiment, subject to the general limitation mentioned below, that two non-matrixed polymer layers cannot generally be deposited in juxtaposition.

The method of fabricating the device of FIG. 15 is generally identical to that described in connection with FIGS. 10 and 13, except that the preparation of the light emitting material and the application of the material to the device preferably comprise the two steps of:

3. Preparing at least two light-emitting materials, at least one of them by mixing one or more light emitting polymers with a matrix suspension to generate one of the types of nanocomposites previously described, and another one or more of them being a polymer solution not mixed with a matrix. For example, such a solution may preferably be obtained by simply dissolving the polymer in an organic solvent such as xylene or toluene.
4. At least one of the two sorts of light-emitting layers made of the light-emitting materials prepared by the methods of step 3, are applied to the underlying layers of the device, whether a PEDOT-PSS layer or the substrate, thus creating a multilayered light emitting structure as the basis of the device.

Referring again to the device shown in the embodiment of FIG. 15, the light emitting structure may preferably comprise three light-emitting layers, 151, 152, 153, emitting light of blue, green and red colors. Preferably, the blue light emitting layer 151 is closer to the device substrate, which is the transparent output window of the device, and the red light emitting layer 153 is further away from the device substrate. This order is required since if the order were reversed, the higher energy blue emitted light could be absorbed by the green and red emitters, and likewise, the green emission could be absorbed by the red emitter. Therefore, it is preferable that the blue emitter be closest to the output window, and the red emitter the furthest. The obverse is also generally true, in that the blue and green layers are transparent to the red emission, and the blue layer is generally transparent to the green.

According to further preferred embodiments, the first layer deposited is from a raw polymer solution not mixed with a matrix, while the second layer deposited, moving in a direction away from the substrate, is from a polymer solution mixed with a matrix. This illustrates a further preferred advantage of the present invention, in that a multilayer device can be produced from two solutions deposited sequentially and in direct contact, due to the incompatibility between the solvents used for polymers and those used for the nanocomposites. The nanocomposites are deposited from alcoholic suspensions while the raw polymers are generally insoluble in alcohols. This solvent incompatibility enables the sequential deposition of layers to form a stack of emitting layers without the layers intermixing.

In such multilayer devices, the layers of light emitting materials can be kept discrete, such that each emits independently, and mixing of two adjacent layers is avoided, or is at least minimized, on condition that the two adjacent layers are not both non-matrixed polymer solutions. In the preferred embodiment shown in FIG. 15, the first layer is made of a polymer solution without a matrix, while the second and third layers are made of polymer solutions with matrix suspensions, this being an implementable combination.

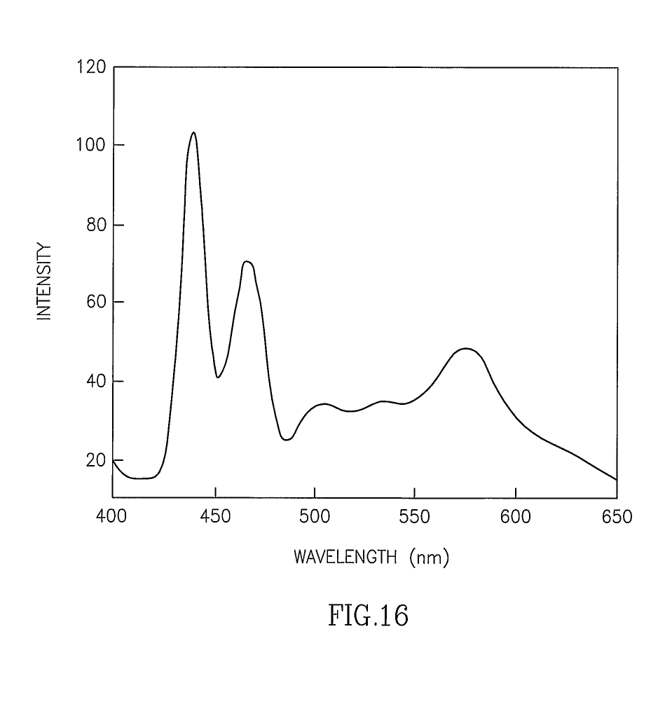

Reference is now made to FIG. 16, which shows the photoluminescence spectra of the multilayer films used in the device of the embodiment of FIG. 15, when excited at 380 nm.

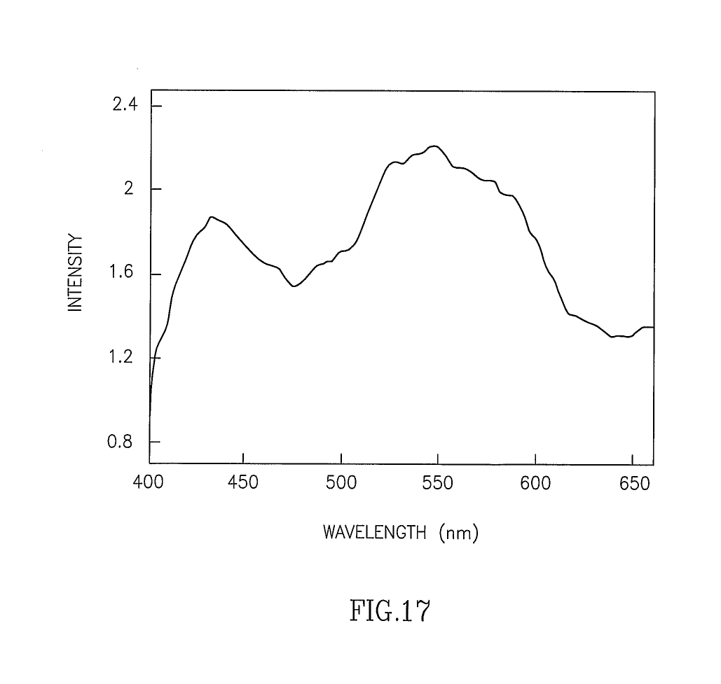

Reference is now made to FIG. 17, which shows the electroluminescence output spectrum from a device of the type shown in FIG. 15, fabricated with multiple layers of polymer emitters, incorporating a layer of unmixed PFO polymer, followed by layers of F8BT and MEH-PPV polymers within SnS₂ matrices. As can be clearly seen from the graph, a wide spectrum of light is emitted, demonstrating the inhibition of energy transfer among the different polymer layers, and the generation of a white light output.

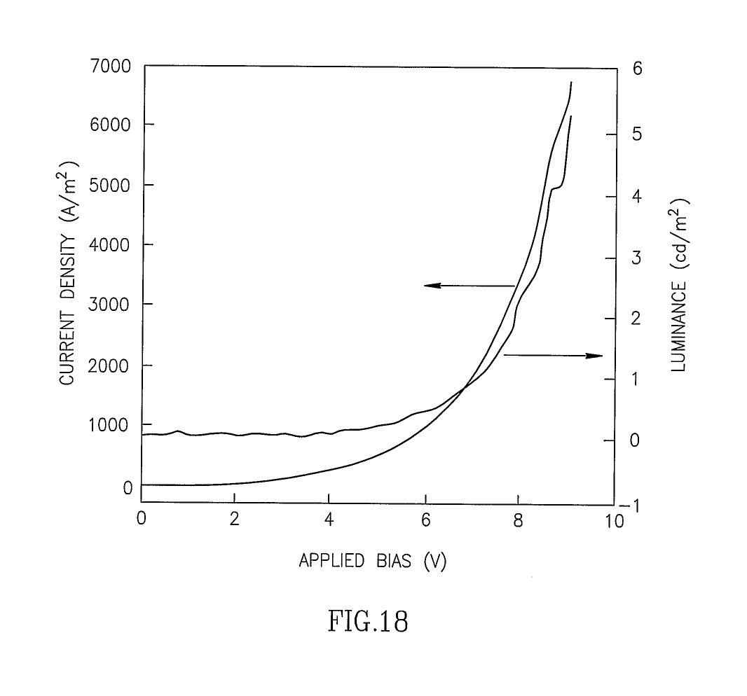

Reference is now made to FIG. 18, which is a graph showing the current-voltage-luminance characteristics of a device of the type shown in FIG. 15.

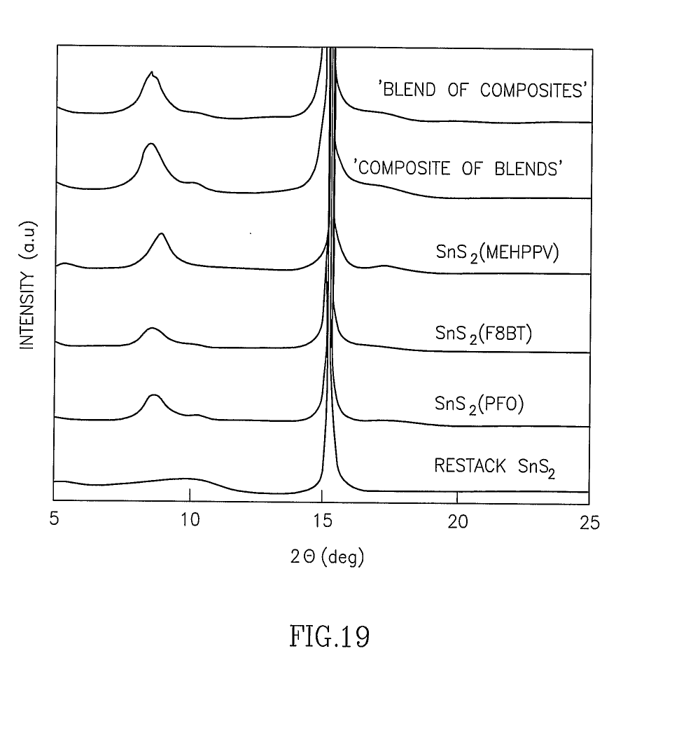

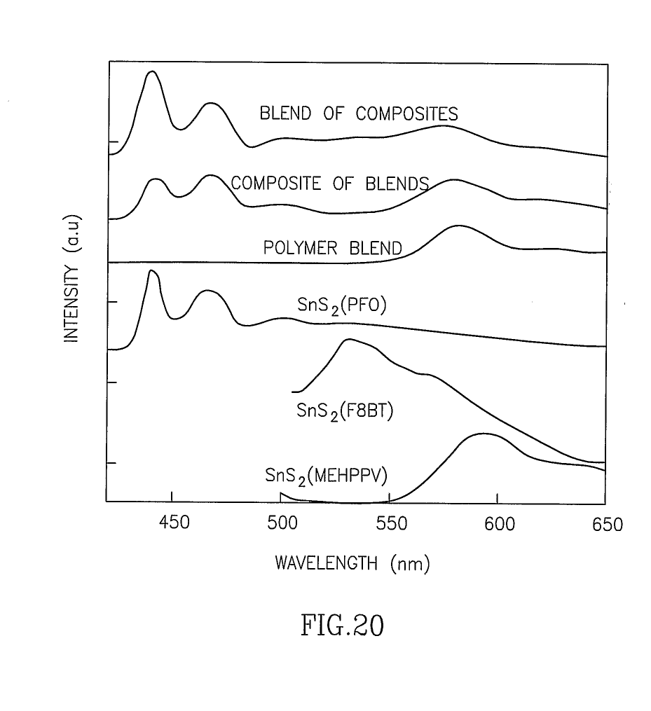

Finally, reference is now made to FIGS. 19 and 20, which illustrate respectively some X-ray diffraction measurements and some photoluminescence spectra which support the mechanisms proposed herein regarding the generation of the EL emission by the methods of the present invention, and the operation of the devices proposed using the materials of the present invention.

Reference is first made to FIG. 19, which shows X-ray diffraction (XRD) patterns of (a) films of restacked SnS₂ without polymer, (b) films with each polymer separately, (c) films with a polymer-blend (‘composite of blend’) intercalated, and (d) films with the mixture of composites (‘blend of composites’). All of the patterns show a strong narrow reflection at 5.8 Å (2θ=15.0°) which corresponds to the c-axis inter-layer spacing of SnS₂ single crystals. The composite XRD patterns also show a new strong reflection at ˜10.4 Å (2θ=8.5°) associated with the intercalation of polymers into the layered galleries. The ˜4.6 Å expansion of the interlayer spacing obtained, regardless of which polymer was intercalated, is in good agreement with the 4.2-5.2 Å c-axis expansion observed for conjugated polymer-intercalated layered compounds. This general interlayer increase is due to the tendency of conjugated polymers to adopt a planar conformation, and indicates that each SnS₂ interlayer spacing accommodates a polymer monolayer only. This feature explains why there is no interaction between species in the ‘blend of composites’ materials, since the available intra-layer height means that there is negligible face-to-face contact between separate polymer monolayers. The same c-axis expansion is noted both for the ‘composite of blend’ and ‘blend of composites’ films, demonstrating that in both cases, only a planar polymer monolayer is isolated between the inorganic sheets. The ‘blend of composites’ film is composed of plate-like particles each composed of SnS₂ layers confining either blue-, green- or red-emitting monolayers, while the “monochromatic” particles are randomly mixed forming the film. In the ‘composite of blend’ particles, on the other hand, each monolayer could contain all three polymers.

As previously mentioned, the tendency of the inorganic host to accommodate a single polymer layer in the galleries hinders polymer π-π stacking and, consequently, reduces interchain interactions. The control over interchain energy transfer is manifested in the photoluminescence (PL) spectra of the confined polymers for the “blend of composites” and the “composite of blends”.

Reference is now made to FIG. 20 which shows a number of PL spectra, to illustrate this. The lower three traces are the PL spectra of SnS₂(MEHPPV), SnS₂(F8BT) and SnS₂(PFO), showing the emission peaks in the Red, Green and Blue respectively. The next trace up is that of a polymer blend, not intercalated into a SnS₂ matrix, but deposited from the same solution used for the intercalation of the nanocomposites. The blend ratio is 10% R, 60% G, 30% B, by weight. Although the blend consists mainly of the blue and green polymer, the PL graph shows that it emits essentially entirely in the red. This is due to the efficient energy transfer from the blue and green-emitting polymers to the red-emitter. On the other hand, if SnS₂ is intercalated with this blend, as shown in the next curve up marked ‘composite of blends’, all of the three emitters contribute separately and independently to the output light, which is consequently a broad spectrum, white-light type of emission. Crucially, this occurs because energy apparently cannot flow from the high-gap blue and green-emitting polymer chains to the low-gap red-emitting polymer chains, despite their close proximities (<200 nm) in single SnS₂ grains, owing to diminished polymer-polymer π-stacking. Each multicolor intercalated composite grain is, therefore, a white light source which could find use in micrometer-sized devices and high-resolution displays. White-light emission is also obtained by blending composites of SnS₂ (blue emitter), SnS₂ (green emitter) and SnS₂ (red emitter) as shown in the top curve of FIG. 20, marked ‘blend of composites’.

Although most of the preferred embodiments of the present invention have been described in terms of three emitting polymeric species, it is to be understood that the invention is understood to be equally applicable to devices and methods using only two species, or more than three species.

It is appreciated by persons skilled in the art that the present invention is not limited by what has been particularly shown and described hereinabove. Rather the scope of the present invention includes both combinations and subcombinations of various features described hereinabove as well as variations and modifications thereto which would occur to a person of skill in the art upon reading the above description and which are not in the prior art.

1.-39. (canceled)

40. An electroluminescent composite material comprising:
at least two light-emitting polymers, each of the polymers emitting light over different wavelength ranges; and
a layered inorganic host,
wherein the at least two of light-emitting polymers are intercalated between layers of the host, such that the luminescent composite material emits a combination of the light emitted by the at least two polymers over the different wavelength ranges.

41. The luminescent composite material according to claim 40, wherein the ratio of the at least two light-emitting polymers is selected such that the combination of the light emitted by the polymers over the different wavelength ranges generates light of a predetermined wavelength.

42. The luminescent composite material according to claim 41, and wherein the at least two light-emitting polymers are three light emitting polymers whose emission is located in the red, green and blue regions of the spectrum such that the combination of the light emitted by the polymers over the different wavelength ranges generates white light.

43. The luminescent composite material according to claim 40, wherein the layered inorganic host is a layered semiconductor material or a layered semiconductor material blended with an insulator.

44. The luminescent composite material according to claim 40, wherein the material comprises a mixture of two portions of the layered host material, each of the portions comprising the inorganic host having one of the at least two light-emitting polymers intercalated between its layers.

45. The luminescent composite material according to claim 40, wherein the inorganic host is selected from the group consisting of semiconducting layered metal dichalcogenides, metal monochalcogenides, metal halides and metal oxides, and blends thereof with insulating layered metal dichalcogenides, metal monochalcogenides and metal oxides, and wherein the light-emitting polymers are selected from the group consisting of light-emitting conjugated polymers, light-emitting non-conjugated polymers, organic low-molecular weight light-emitting materials, and copolymers of organic low-molecular weight light-emitting materials.

46. The luminescent composite material according to claim 40, wherein the light-emitting conjugated polymers comprise at least one of a poly(p-phenylenevinylene) compound, a polythiophene compound, a poly(p-phenylene) compound, a polyfluorene compound, a polyquinoline compound, a polyacetylene compound, and a polypyrrole compound; and the light-emitting non-conjugated polymer comprises a poly(9-vinylcarbarzole) compound.

47. An electroluminescent device, comprising in the following spatial order:
a substrate;
a first electrode deposited over the substrate;
a luminescent layer; and
a second electrode,
wherein the luminescent layer comprises a luminescent composite material according to claim 40.

48. The electroluminescent device of claim 47, further comprising a second luminescent layer and which includes the following spatial order:
a substrate;
a first electrode deposited over the substrate;
at least two luminescent layers; and
a second electrode,
wherein the second luminescent layer comprises at least one layer of a non-composite light-emitting polymer.

49. The electroluminescent device according to claim 48, wherein the substrate is selected from the group consisting of glass, quartz, and PET (polyethylene terephtalate), the first electrode is selected from the group consisting of ITO (indium tin oxide), zinc-doped indium oxide (IZO), indium oxide, tin oxide and zinc oxide, PEDOT(polyethylene dioxythiophene), and polyaniline.

50. The electroluminescent device according to claim 48, wherein the first electrode is selected from the group consisting of ITO (indium tin oxide), zinc-doped indium oxide (IZO), indium oxide, tin oxide and zinc oxide, PEDOT(polyethylene dioxythiophene), and polyaniline and wherein the second electrode is selected from the group consisting of aluminum, magnesium, lithium, calcium, copper, gold, potassium, sodium, lanthanum, cerium, strontium, barium, silver, indium, tin, zinc, zirconium, and binary or ternary alloys containing combinations of these.

51. The electroluminescent device according to claim 48, further comprising a hole transporting layer formed between the first electrode and a luminescent layer, wherein the hole transporting layer is composed of one or more materials which are selected from the group consisting of polymers including polyvinylcarbazole and its derivatives; organic low-molecular materials including 4,4′-dicarbazolyl-1,1′-biphenyl-(CBP), TPD(N,N′-diphenyl-N,N′-bis-(3-methylphenyl)-1,1′-biphenyl-4,4′-diam-ine), NPB(4,4′-bis[N-(1-naphthyl-1-)-N-phenyl-amino]-biphenyl), triarylamine, pyrazoline and their derivatives; and organic low-molecular and polymer materials containing a hole transporting moiety.

52. The electroluminescent device according to claim 48, further comprising an electron transporting layer formed between a luminescent layer and the second electrode, wherein the electron transporting layer is composed of one or more materials which are selected from the group consisting of TPBI(2,2′,2′-(1,3,5-phenylene)-tris[1-phenyl-1H-benzimidaz-ole]), poly(phenyl quinoxzline), 1,3,5-tris[(6,7-dimethyl-3-phenyl)quinoxa-line-2-yl]benzene(Me-TPQ), polyquinoline, tris(8-hydroxy quinoline)aluminum(Alq3), {6-N,N-diethylamino-1-methyl-3-phenyl-1H-pyrazo-lo[3,4-b]quinoline}(PAQ-Net2), and low-molecular weight and polymer materials containing an electron transporting moiety.

53. A method of preparing a luminescent nanocomposite material, which comprises:
providing at least two light-emitting polymers, each of the polymers emitting light over different wavelength ranges;
providing a layered inorganic host; and
intercalating the at least two light-emitting polymers between layers of the layered inorganic host.

54. The method according to claim 53, wherein the intercalating comprises:
producing an alkali metal intercalated compound of the layered inorganic host;
exfoliating the alkali metal intercalated compound of the inorganic host in a first solvent to generate a suspension;
mixing the light emitting polymers in a second solvent compatible with the first solvent, to generate a solution;
mixing the suspension and the solution to produce a flocculated composite material of the light emitting polymers intercalated into the layered inorganic host; and
washing the flocculated composite material with an organic solvent to remove traces of non-intercalated polymer.

55. The method according to claim 54, wherein the alkali metal is selected from a group consisting of lithium, sodium and potassium, wherein the first solvent is selected from a group consisting of water, an alcohol, and a combination thereof, wherein the second solvent is selected from a group consisting of dichloromethane, chloroform, benzene, toluene, xylene, anisole, cresol, nitrobenzene, dichlorobenzene, tetrahydrofuran, dimethoxyethane, N,N-dimethylformamide, N,N-dimethylacetamide, N-methylpyrrolidone, and wherein the organic solvent is selected from a group consisting of dichloromethane, chloroform, benzene, toluene, xylene, anisole, cresol, nitrobenzene, dichlorobenzene, tetrahydrofuran, dimethoxyethane, N,N-dimethylformamide, N,N-dimethylacetamide, N-methylpyrrolidone.

56. The method according to claim 53, wherein the layered inorganic host comprises a semiconductor material selected from the group consisting of semiconducting layered metal dichalcogenides, metal monochalcogenides, metal halides and metal oxides, and blends thereof with insulating layered metal dichalcogenides, metal monochalcogenides and metal oxides.

57. The method according to claim 53, wherein the intercalating of the first of the light-emitting polymers between the layers of the layered inorganic host produces a first nanocomposite; and the method further comprises:
intercalating a second one of the at least two light-emitting polymers between layers of the layered inorganic host to produce a second nanocomposite; and
mixing the first nanocomposite and the second nanocomposite to form the luminescent material.

58. A method of providing luminescent emission at a predetermined wavelength, which comprises:
determining the chromaticity co-ordinates of the predetermined wavelength on a chromaticity diagram;
providing a luminescent composite material according to claim 53 with the pair of light-emitting polymers selected such that a straight line connecting the color co-ordinates of their emission on the chromaticity diagram passes through the region of the predetermined wavelength;
determining the relationship between the ratio of the light emitting polymers in the luminescent composite material and the emission color along the connecting line for a limited number of the ratios; and
using the relationship to select the ratio of the light-emitting polymers, such that the luminescent emission obtained is that of the predetermined wavelength.

59. The method according to claim 58, wherein the luminescent composite material comprises three light-emitting polymers selected such that the chromaticity co-ordinates of the predetermined wavelength falls within a triangle having the three colors at its apices
